(19) United States
(12) Patent Application Publication
(10) Pub. No.: US 2025/0014971 A1
(43) Pub. Date: Jan. 9, 2025

(54) Power Package With Galvanic Isolation

(71) Applicant: Infineon Technologies Austria AG, Villach (AT)

(72) Inventors: Richard Knipper, Regensburg (DE); Frank Singer, Regensburg (DE); Edward Fürgut, Dasing (DE); Dexter Inciong Reynoso, Singapore (SG)

(21) Appl. No.: 18/346,932

(22) Filed: Jul. 5, 2023

(51) Int. Cl. H01L 23/495; H01L 23/00

(52) U.S. Cl. CPC H01L 23/49562; H01L 23/49503; H01L 23/49575; H01L 24/32; H01L 24/48; H01L 24/73; H01L 2224/32225; H01L 2224/48247; H01L 2224/73265; H01L 2924/13055; H01L 2924/13091

(57) ABSTRACT

A semiconductor package includes an input side including input pins an output side including high voltage pins, an isolation structure that galvanically isolates the input side from the output side, an input driver die mounted on the input side and electrically connected with the input pins, first and second power transistor dies mounted on the output side and each having a first load terminal electrically connected with the high voltage pins, an output driver die that is communicatively coupled to the input driver die driver die via the isolation structure and is electrically connected with gate terminals of the first and second power transistor dies, and one or more electrically conductive structures forming a direct electrical connection between load terminals of the first and second power transistor dies, wherein the output driver die is mounted on one of the one or more electrically conductive structures.

### BACKGROUND

An integrated power device package such as a relay circuit may include power switching devices, e.g., IGBTs (insulated gate bipolar transistors), MOSFETs (metal oxide semiconductor field effect transistors), HEMTs (high electron mobility transistors) in combination with a gate driver device that controls the switching of the power switching devices. The power switching devices experience large voltage drops on the order of 600 V, 1200 V, 2400 V or more during operation. The gate driver device on the other hand is a low-voltage device that operates at voltages on the order of 5 V, 10 V, 15V or even 30 V or above. An integrated power device package may therefore include a high voltage plane used to provide supply voltage to the power switching devices and a low voltage plane used to provide supply voltages to the gate driver device. Electrical isolation is needed between the gate driver device and the high voltage plane to prevent device destruction and failure. It is desirable to provide a semiconductor package that electrically isolates a driver device from power switching devices in a space efficient manner.

### SUMMARY

A semiconductor package is disclosed. According to an embodiment, the semiconductor package comprises an input side comprising one or more input pins, an output side comprising a plurality of high voltage pins an isolation structure that galvanically isolates the input side from the output side, an input driver die driver die mounted on the input side and electrically connected with the input pin, first and second power transistor dies mounted on the output side and each having a first load terminal electrically connected with one of the high voltage pins, an output driver die that is communicatively coupled to the input driver die driver die via the isolation structure and is electrically connected with gate terminals of the first and second power transistor dies, and one or more electrically conductive structures forming a direct electrical connection between second load terminals of the first and second power transistor dies, wherein the output driver die is mounted on at least one of the one or more electrically conductive structures.

According to an embodiment, the semiconductor package comprises an input side comprising an input pin, an output side comprising high voltage pins, an isolation structure that galvanically isolates the input side from the output side, an input driver die driver die mounted on the input side and electrically connected with the input pin, first and second power transistor dies mounted on the output side and each having a first load terminal electrically connected with one of the high voltage pins, an output driver die comprising an input terminal that is communicatively coupled to the input driver die driver die via the isolation structure and output terminals that are electrically connected with gate terminals of the first and second power transistor dies, and an interconnect bridge that is mounted over the first and second power transistor dies and extends directly from a second load terminal of the first power transistor die to a second load terminal of the second power transistor die, wherein the isolation structure is integrally formed within the interconnect bridge.

A method of forming a semiconductor package is disclosed. According to an embodiment, the method of forming the semiconductor package comprises providing a circuit carrier that comprises a first input device pad, first and second output device die pads, a plurality of input pins, and a plurality of output pins, mounting an input driver die driver die on the first input device pad and electrically connecting the input driver die to one of the input pins, mounting first and second power transistor dies on the first and second output device die pads, respectively, and electrically connecting first load terminals of the first and second power transistor dies with the output pins, providing an isolation structure that galvanically isolates an input side of the semiconductor package from an output side of the semiconductor package, and mounting an output driver die on the output side of the semiconductor package such that the output driver die is communicatively coupled to the input driver die driver die via the isolation structure and is electrically connected with gate terminals of the first and second power transistor dies, forming a direct electrical connection between second load terminals of the first and second power transistor dies, and forming an electrically insulating encapsulant body that encapsulates each of the input driver die, the output driver die driver, and the first and second power transistor dies, wherein the output driver die is mounted on one or more electrically conductive structures that form a direct electrical connection between second load terminals of the first and second power transistor dies.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 schematically illustrates a semiconductor package with a galvanically isolated switching device, according to an embodiment.

FIG. 2 illustrates an interior assembly of a semiconductor package, according to an embodiment.

FIG. 3, which includes FIGS. 3A-3F, illustrates selected method steps in a method of forming a semiconductor package, according to an embodiment.

FIG. 4 illustrates an interior assembly of a semiconductor package, according to an embodiment.

FIG. 5 illustrates an interior assembly of a semiconductor package, according to an embodiment.

FIG. 6 illustrates an interior assembly of a semiconductor package, according to an embodiment.

FIG. 7 illustrates an interior assembly of a semiconductor package, according to an embodiment.

FIG. 8, which includes FIGS. 8A and 8B, illustrates an interior assembly of a semiconductor package, according to an embodiment. FIG. 8A illustrates a plan-view of the assembly and FIG. 8B illustrates a cross-sectional view of an interconnect bridge from the assembly.

### DETAILED DESCRIPTION

Embodiments of a semiconductor package with a galvanically isolated switching device and corresponding method of forming the semiconductor package are described herein. The embodiments facilitate a semiconductor package with an advantageously small size and output pin count. Further, the semiconductor package may be configured with current sensing functionality for sensing a current flowing through the power switching devices while maintaining the advantageously small size and output pin count. The switching device of the semiconductor package is provided by multiple series connected power transistor dies provided on an output side of the semiconductor package. These power transistor dies are driven by an output driver that is galvanically isolated from an input side of the semiconductor package by a galvanic isolation structure. The input side of the semiconductor package comprises an input driver that can operate on a different voltage domain due to the galvanic isolation. The semiconductor package is configured such that there is a direct internal electrical connection between the load terminals of the power transistor dies. Moreover, at least parts of the output driver are mounted on or incorporated into the features which form the direct internal electrical connection between the load terminals of the power transistor dies. This arrangement advantageously reduces the package footprint by eliminating the need for a dedicated area, e.g., in the form of a die pad, to accommodate at least parts of the output driver. Moreover, this arrangement allows for the placement of a current sensor device on the features which form the direct internal electrical connection between the load terminals of the power transistor dies. This eliminates the need for dedicated externally accessible high voltage pins for the connection of a current shunt, thus further facilitating a reduction in the package footprint and improving creepage and clearance between the high voltage terminals of the device.

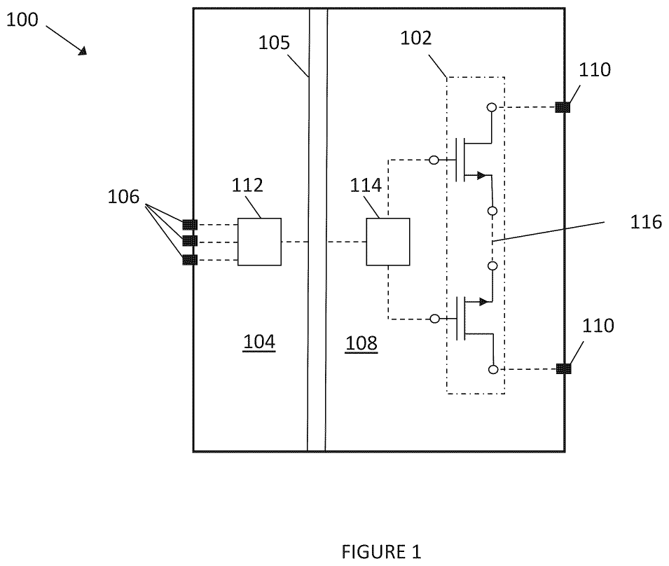

Referring to FIG. 1, a semiconductor package 100 with a galvanically isolated switching device 102 is schematically depicted, according to an embodiment. The semiconductor package 100 comprises an input side 104 comprising one or more input pins 106 and an output side 108 comprising a plurality of high voltage pins 110. The semiconductor package 100 further comprises an isolation structure 105 that galvanically isolates the input side 104 from the output side 108. Galvanic isolation refers to the provision of an electrical structure that prevents all current flow between the galvanically isolated components, while energy and/or information may be conveyed by other means, e.g., electromagnetically, optically, acoustically, mechanically, etc. The isolation structure 105 may include a high breakdown strength electrical isolating medium, e.g., SiO₂ (silicon dioxide), Si₃N₄ (silicon nitride), SiOₓN_{y} (silicon oxynitride), low doped semiconductor material, glass, etc. in between two conductors, while permitting a communicative connection between the two conductors via coupling. According to an embodiment, the isolation structure 105 comprises a coreless transformer having first and second coils that are isolated from one another by an isolation barrier that comprises insulating material. In other embodiments, the isolation structure 105 may include any one of the following: optocoupler devices, capacitive coupling devices, inductive coupling devices, and radiative coupling devices. The isolation structure 105 allows for the input side 104 of the semiconductor package 100 to operate at a different voltage domain than the output side 108 of the semiconductor package 100. The input side 104 of the semiconductor package 100 may operate at voltages on the order of, e.g., 15 V, 10 V, or less. The output side 108 of the semiconductor package 100 may operate at voltages on the order of, at least 100 V and more typically 600 V, 1200 V or more.

The semiconductor package 100 comprises an input driver circuit 112 disposed on the input side 104 and electrically connected with the input pins 106. The input driver circuit 112 is a logic circuit that is configured to generate switching signals for switching a switching device 102 that is disposed on the output side 108 of the semiconductor package 100. The input driver circuit 112 may comprise other functionality to adjust the switching of the switching device 102 and/or protect the switching device 102 from potentially damaging conditions such as short circuit conditions, overvoltage conditions, etc. The semiconductor package 100 further comprises an output driver circuit 114 disposed on the output side 108. The output driver circuit 114 is communicatively coupled to the input driver circuit 112 via the isolation structure 105. The output driver circuit 114 is a logic circuit that is configured to receive switching signals form the input driver circuit 112 and to convey these switching signals in the form of gate biases to the switching device 102. The switching device 102 comprises a plurality of transistors that are connected in series with one another between the high voltage pins 110. As shown, the transistors which form the switching device 102 are implemented as MOSFETs (Metal Oxide Semiconductor Field Effect Transistors). More generally, the transistors which form the switching device 102 may be implemented using any kind of transistor deice, e.g., IGBTs (Insulated Gate Bipolar Transistors), HEMTs High Electron Mobility Transistors, wide-bandgap based technologies such as silicon carbide (SiC), gallium nitride (GaN) or gallium oxide (GaO), etc. While the switching device 102 of the depicted embodiment includes two transistors connected in series in one another, more generally, the switching device 102 may be realized by any plurality of power transistors connected in series with one another between the high voltage pins 110.

The semiconductor package 100 comprises a direct electrical internal connection 116 between load terminals of the transistors that form the switching device 102. The direct electrical internal connection 116 is formed by one or more electrically conductive structures connected between the load terminals of the series connected transistors. These electrically conductive structures can include electrical interconnect elements, e.g., bond wires, interconnect clips, interconnect ribbons, etc. Separately or in combination, these electrically conductive structures can include portions of a metal lead frame including die pads and dedicated metal tracks. Separately or in combination, these electrically conductive structures can be provided by the metallization layer of a circuit carrier with a similar or identical construction as a PCB (printed circuit board) or power electronics carrier such as a DCB (direct copper bonded) substrate, IMS (insulated metal substrate), or AMB (active metal brazed substrate). The output driver circuit 114 may be a device or devices that is/are mounted on one or more of the electrically conductive structures that form the direct electrical internal connection 116. Separately or in combination, the output driver circuit 114 may include devices or circuits that are monolithically integrated within one or more of the structures that is/are used to form the direct electrical internal connection 116 between the load terminals of the transistors that form the switching device 102.

The working principle of the semiconductor package 100 is as follows. The input driver circuit 112 receives switching information at one of the input pins 106 and comprises a signal modulator such as a PWM (pulse width modulation) modulator that conveys this information to the output driver circuit 114 via the galvanically isolated communication link. The output driver circuit 114 correspondingly includes a signal demodulator such as a PWM demodulator for demodulating the switching control information transferred from the input driver die. Based on the demodulated switching control information, the output driver circuit 114 generates switching signals that are applied to the gate terminals of the power transistors, thereby switching these devices. In certain operational states of the power transistor dies and/or in short circuit conductions, the high operational voltages from the output side 108 of the semiconductor package 100 may appear at the internal load terminals of the power transistors. The galvanic isolation between the output side 108 of the semiconductor package 100 and the input side 104 of the semiconductor package 100 ensures that the input driver circuit 112 is not exposed to these potentially destructive voltages while simultaneously providing a communication path for the input driver circuit 112 to convey switching signals to the output driver circuit 114.

According to an embodiment, the semiconductor package 100 comprises a current sensor that is configured to sense a current flowing through the switching device 102. The current sensor may be part of the same device that includes the output driver circuit 114 and/or may be mounted on the structures that form the direct electrical internal connection 116. The information sensed by the current sensor may be conveyed back to the input driver circuit 112 via the galvanically isolated transmission path, which in turn may be used by the input driver circuit 112 to adjust the control signaling. By providing a current sensor within the semiconductor package 100 in this manner, the semiconductor package 100 does not require dedicated pins (terminals) at the output side 108 of the package that are coupled to the load terminals of the switching device 102 and are used to place an external shunt across the across the switching device 102 to perform current measurement.

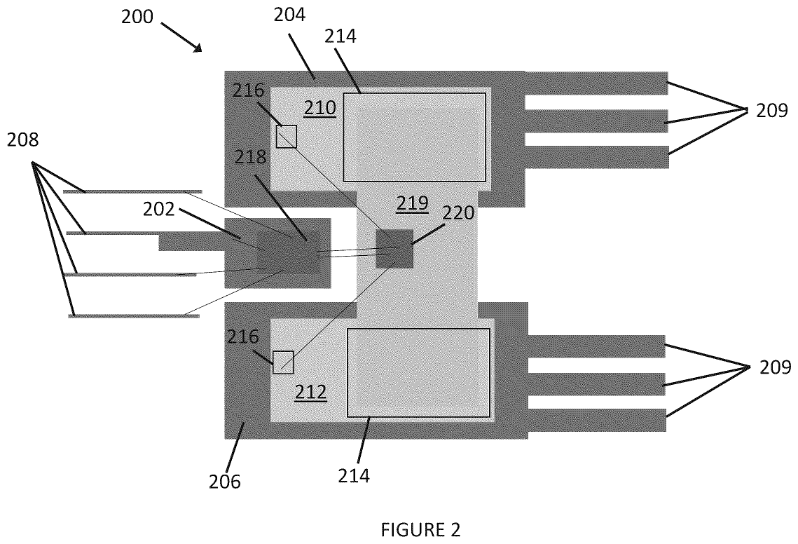

Referring to FIG. 2, an assembly used to form the semiconductor package 100 is shown, according to an embodiment. The assembly comprises a circuit carrier 200. In this embodiment, the circuit carrier 200 is configured as a metal lead frame. The metal lead frame comprises an input device pad 202, a first output device pad 204, a second output device pad 206, a plurality of input leads 208, and a plurality of output leads 209. The input leads 208 correspond to the input pins 106 from the semiconductor package 100 and the and the output leads 209 correspond to the high voltage pins 110 from the semiconductor package 100 in the above description.

First and second power transistor dies 210, 212 are mounted on the first and second output device die pads 204, 206, respectively. The first and second power transistor dies 210, 212 collectively form the switching device 102 from the semiconductor package 100 in the above description. The first and second power transistor dies 210, 212 are discrete transistor dies that are rated to accommodate voltages and currents associated with power applications, e.g., voltages of at least 100 V (volts) and may be on the order of 600 V, 1200 V or more and/or currents of at least 1A and may be on the order of 10A, 50A, 100A or more. Examples of the first and second power transistor dies 210, 212 include discrete MOSFETs (Metal Oxide Semiconductor Field Effect Transistors), discrete IGBTs (Insulated Gate Bipolar Transistors), and discrete HEMTs (High Electron Mobility Transistors), etc. The first and second power transistor dies 210, 212 each comprise a first load terminal (not seen in FIG. 1) that faces the circuit carrier 200 and a second load terminal 214 that faces away from the circuit carrier 200. The first load terminal and the second load terminal 214 refer to the device terminals that accommodate the rated voltage/current, i.e., the drain and source terminals in the case of a MOSFET, the collector and emitter terminals in the case of an IGBT, and so forth. The first and second power transistor dies 210, 212 in the depicted embodiment have a vertical device configuration wherein the device is configured to conduct a load current between opposite facing main and rear surfaces of the die. In other embodiments, the first and second power transistor dies 210, 212 may be configured as lateral devices, which refers to a type of device that conducts a load current in a lateral direction parallel to a main surface. The first and second power transistor dies 210, 212 each additionally comprise a gate terminal 216 that that faces away from the circuit carrier 200 in the depicted embodiment.

The semiconductor package 100 comprises an interconnect bridge 219 mounted on top of the the first and second power transistor dies 210, 212 and extending across a gap between the first and second output device die pads. The interconnect bridge 219 forms the direct electrical internal connection 116 between load terminals of the transistors as described above. That is, the interconnect bridge 219 may form a direct electrical between the source terminals of first and second power transistor dies 210, 212 that are configured as MOSFETs, and may may form a direct electrical between the collector terminals of first and second power transistor dies 210, 212 that are configured as IGBTs, and so forth.

In the embodiment of FIG. 2, the interconnect bridge is configured as a metal interconnect clip. This metal interconnect clip may be attached and directly electrically connected to the second load terminals 214 of the first and second power transistor dies 210, 212 using a conductive adhesive, e.g., solder, sinter, etc.

The assembly comprises an input driver die 218 mounted on the input device pad 202. The input driver die 218 is a logic die that is configured to provide the functionality from the semiconductor package 100 in the above description. The input driver die 218 may be silicon-based IC, for example.

The assembly comprises an output driver die 220. The output driver die 220 is a driver die that is configured to provide the functionality of the output driver circuit 114 from the semiconductor package 100 in the above description. To this end, the output driver die 220 is electrically connected with the gate terminals 216 of the first and second power transistor dies 210, 212. This electrical connection may be provided by interconnect elements, such as bond wires (as shown), ribbons, clips, etc. In the depicted embodiment, the output driver die 220 is mounted on the interconnect bridge 219. Thus, the output driver die 220 is mounted directly on the structure that accommodates the current flowing through the first and second power transistor dies 210, 212. The output driver die 220 may be silicon-based or silicon carbide-based device, for example.

The input driver die 218 and the output driver die 220 are communicatively coupled to one another by an isolation structure 105 as described with reference to FIG. 1. In the depicted embodiment, the isolation structure 105 is monolithically integrated within the output driver die 220. For example, the output driver die 220 may comprise a coreless transformer separating an input pad of the output driver die 220 from output driver circuitry of the output driver die 220, which in turn is connected to output pads of the output driver die 220 that connect with the first and second power transistor dies 210, 212. In this way, the input driver die 218 may be electrically connected with the input pad of the output driver die 220 by an electrical interconnect element (e.g., a bond wire as shown) while remaining galvanically isolated from the output side 108 of the semiconductor package 100. In other embodiments, the isolation structure 105 may be provided outside of the output driver die 220. For instance, the isolation structure 105 may be provided as a separate discrete element or monolithically integrated into another component of the semiconductor package 100, some examples of which will be disclosed below.

According to an embodiment, the output driver die 220 is configured as a current sensor to sense a current flowing between the second load terminals 214 of the first and second power transistor dies 210, 212. As a result of being mounted directly on the structures forming the direct electrical internal connection 116 between the second load terminals of the power transistors, the output driver die 220 is in close proximity to the current flowing through the first and second power transistor dies 210, 212. The output driver die 220 may comprise sensing elements such as magnetic sensing elements that are configured to translate an observed magnitude of the magnetic field associated with the load current into a signal indicating the magnitude of the load current.

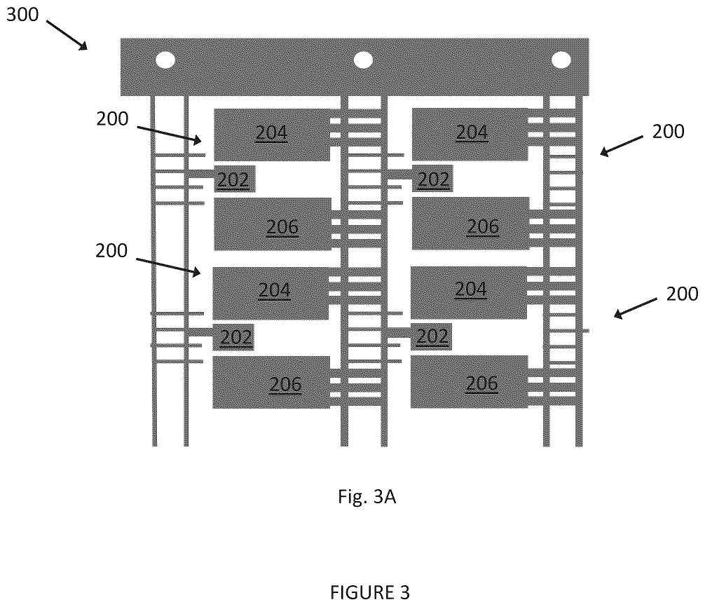

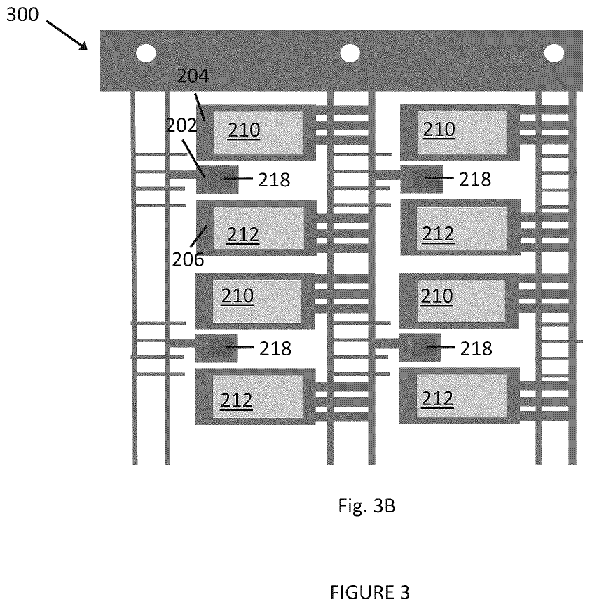

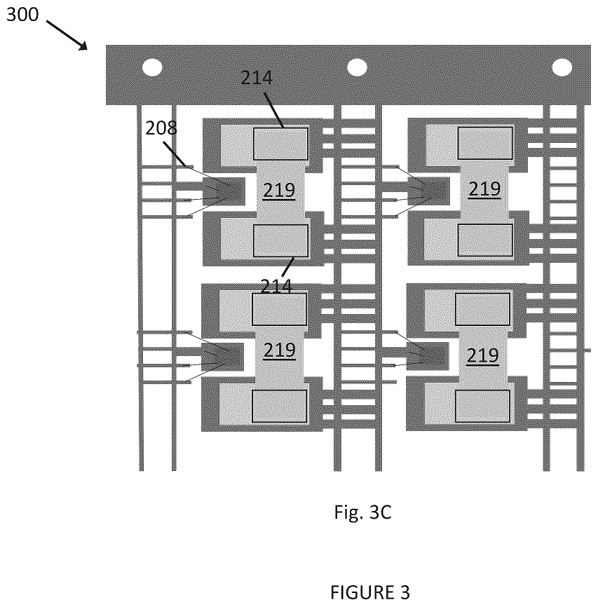

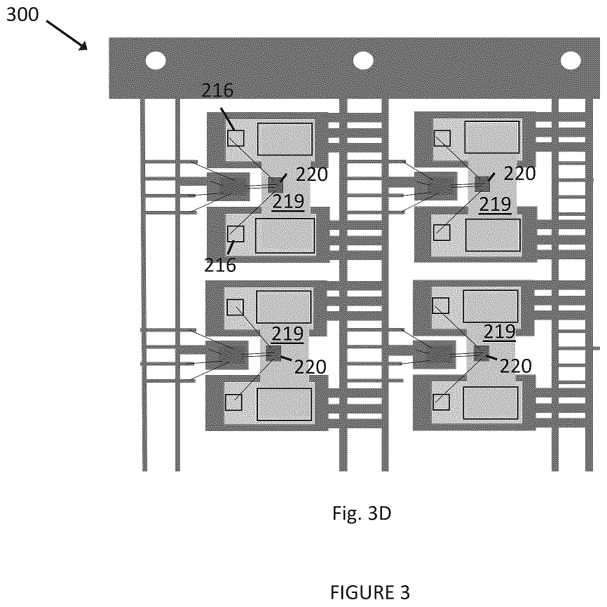

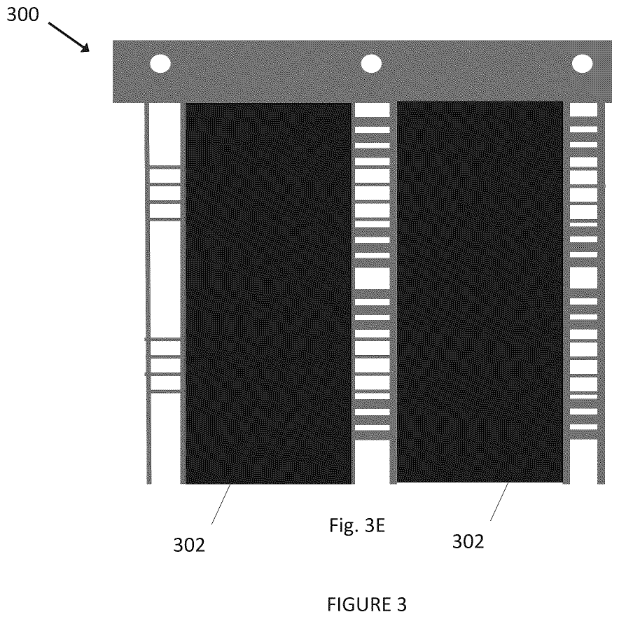

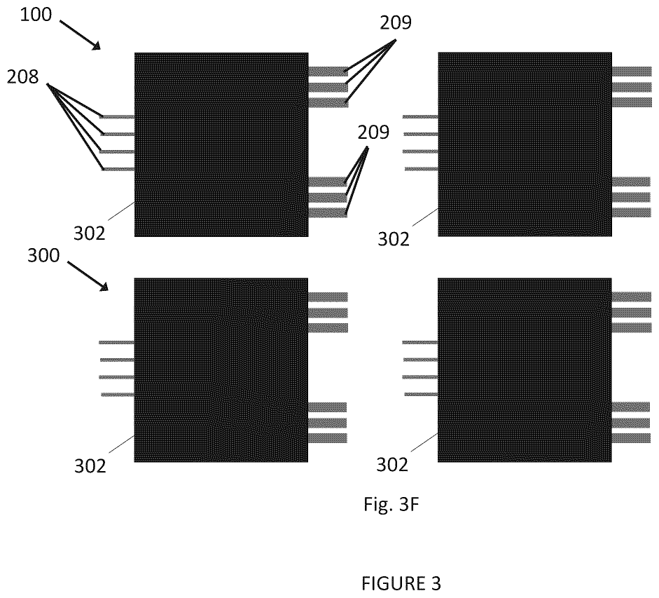

Referring to FIG. 3, selected method steps for forming a semiconductor package assembly described with reference to FIG. 2 are shown.

As shown in FIG. 3A, a lead frame strip 300 is provided. The lead frame strip 300 comprises a plurality of unit lead frames, each of which provide the circuit carrier 200 for one semiconductor package 100. Each of the unit lead frames is connected to the lead frame strip 300 by tie bars and dambars that physically support the features of the lead frame before a trimming process.

As shown in FIG. 3B, for each of the unit lead frames, the input driver die 218 is mounted on the input device die pad 202 and the first and second power transistor dies 210, 212 are mounted on the first and second output device die pads 204, 206, respectively. This may be done using an adhesive such as a solder, sinter, etc.

As shown in FIG. 3C, for each of the unit lead frames, a metal interconnect clip which forms the interconnect bridge 219 is mounted over the first and second power transistor dies 210, 212. The metal interconnect clip may be attached and electrically connected to the second load terminals 214 of the first and second power transistor dies 210, 212 by a conductive adhesive, e.g., solder, sinter, etc. In addition, bond wires are formed between the input driver die 218 and the input leads 208.

As shown in FIG. 3D, for each of the unit lead frames, the output driver die 220 is mounted on the interconnect bridge 219. This may be done by an adhesive, e.g., solder, sinter, glue tape etc. Additionally, bond wires are formed between the output driver die 220 and the gate terminals 216 of the first and second power transistor dies 210, 212.

As shown in FIG. 3E, an encapsulation process is performed to create an electrically insulating encapsulant body 302 that encapsulates the elements mounted on the lead frame strip 300. The encapsulation process may comprise a molding process such as injection molding, transfer molding, compression molding, etc. The encapsulation material may comprise a mold compound comprising epoxy, thermosetting plastic, polymer, etc.

As shown in FIG. 3F, a trimming step has been performed to create multiple individual semiconductor packages 100 from the lead frame strip 300. The trimming step involves severing the input leads 208 and the output leads 209 from the lead frame strip 300. This trimming may be done using any cutting technique, e.g., mechanical sawing, laser ablation, chemical cutting, etc.

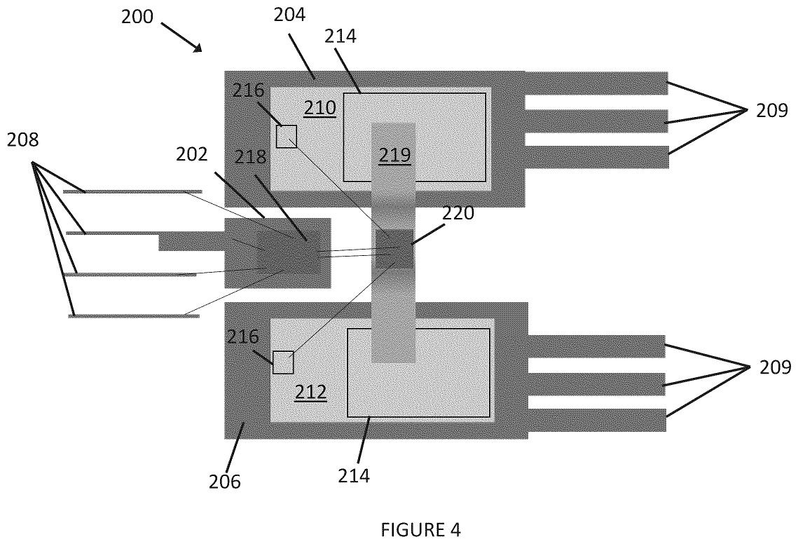

Referring to FIG. 4, an assembly used to form the semiconductor package 100 is shown, according to another embodiment. The assembly of FIG. 4 is identical to that of FIG. 2, except that the interconnect bridge 219 is configured as an interconnect ribbon. This interconnect ribbon is mounted over the first and second power transistor dies 210, 212 and is electrically connected to the second load terminal 214 of the first power transistor die 210 and the second load terminal 214 of the second power transistor die 212. The output driver die 220 is mounted on the interconnect ribbon in a similar manner as described above.

Referring to FIG. 5, an assembly used to form the semiconductor package 100 is shown, according to another embodiment. In this example, the circuit carrier 200 of the semiconductor package 100 is a lead frame with a similar configuration to that of FIG. 2, except that it additionally includes a third output device die pad 226 disposed in the space between the first and second output device die pads 204, 206. The output driver die 220 is mounted on the third output device die pad 226, e.g., using an adhesive such as solder, sinter, glue, tape, etc., and connected to the first and second power transistor dies 210, 212 in a similar manner as described above. The semiconductor package 100 comprises a first plurality 228 of interconnect elements connected between the second load terminal 214 of the first power transistor die 210 and the third output device die pad 226 and a second plurality 230 of interconnect elements connected between the between the second load terminal 214 of the second power transistor die 212 and the third output device die pad 226. The first plurality 228 of interconnect elements and the second plurality 230 of interconnect elements combined with the third output device die pad 226 collectively provide an electrically conductive path akin to the interconnect bridge 219 described above. The output driver die 220 may be configured as a current sensor in a similar manner as described above. As depicted, the interconnect elements from the first plurality 228 and the second plurality 230 are configured as bond wires. Alternatively, these interconnect elements may be configured as other types of interconnect elements such as metal interconnect clips, interconnect ribbons, etc.

As shown, the lead frame comprises a tie bar 232 that connects the third output device die pad 226 with a dambar of the lead frame strip. According to an embodiment, this tie bar 232 is severed along the dashed lines indicated in the figure, e.g., mechanical sawing, laser ablation, chemical cutting, etc. This severing may occur after the first plurality 228 of interconnect elements and the second plurality 230 of interconnect elements are attached to the first and second power transistor dies 210, 212 and the third output device die pad 226 such that the third output device die pad 226 is temporarily suspended by the interconnect elements until an electrically insulating encapsulant body 302 is formed, e.g., according to the technique described with reference to FIGS. 3E and 3F. Once the encapsulant body 302 is formed, an outer end of the tie bar 232 is spaced apart from an outer edge side of the electrically insulating encapsulant body. The tie bar 232 thus becomes an internally isolated structure. As a result, a greater creepage and clearance can be maintained between the output leads 209 of the semiconductor package 100, as the tie bar 232 structure does not form an exposed conductor that impacts creepage and clearance.

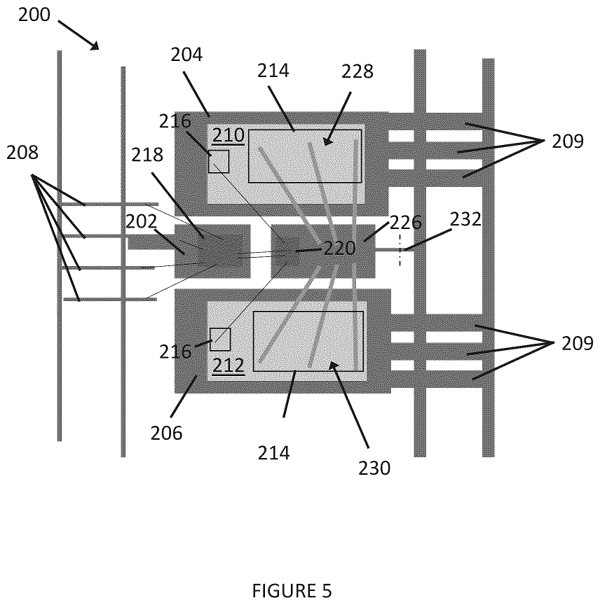

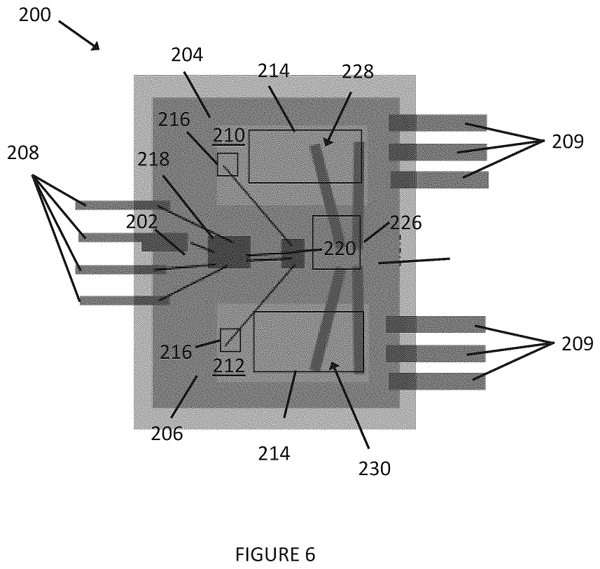

Referring to FIG. 6, an assembly used to form the semiconductor package 100 is shown, according to another embodiment. In this embodiment, the circuit carrier 200 of the semiconductor package 100 is a power electronics carrier that comprises a structured metallization layer disposed on an electrically insulating substrate. The structured metallization layer comprises a plurality of pads that are electrically isolated from one another and have the geometry of the input device die pad 202, the first output device pad 204, the second output device pad 206, and the third output device pad 226 as described above. The structured metallization layer may comprise or be plated with any or more of Cu, Ni, Ag, Au, Pd, Pt, NiV, NiP, NiNiP, NiP/Pd, Ni/Au, NiP/Pd/Au, or NiP/Pd/AuAg. The electrically insulating substrate may comprise a ceramic material such as Al₂O₃ (Alumina) AlN (Aluminium Nitride), etc., or filled polymer materials such as epoxy resin or polyimide. The power electronics carrier may be a Direct Copper Bonding (DCB) substrate, a Direct Aluminium Bonding (DAB) substrate, an Isolated Metal Substrate (IMS) or an Active Metal Brazing (AMB) substrate, for example. Optionally, the isolation structure 105 that provides galvanic isolation between the input side 104 of the semiconductor package 100 and the output side 108 of the semiconductor package 100 may be incorporated into the circuit carrier 200 that is configured as a power electronics carrier. The electrically isolating region of the isolation structure 105 may be provided by the electrically insulating substrate with a second metallization layer (not shown) disposed on an opposite side of the electrically insulating substrate.

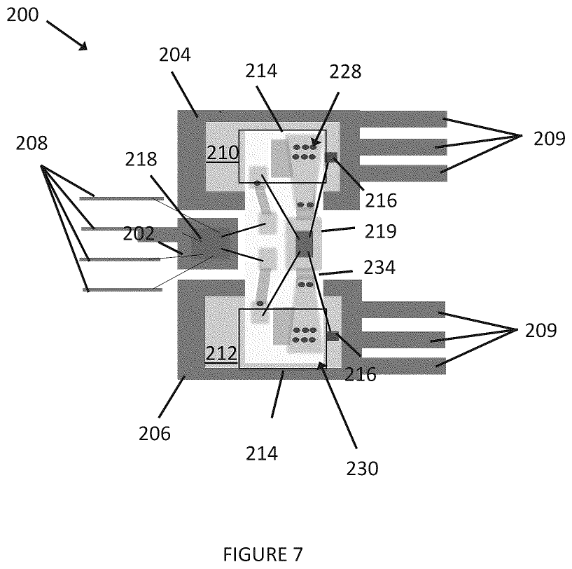

Referring to FIG. 7, an assembly used to form the semiconductor package 100 is shown, according to another embodiment. The assembly of FIG. 7 is similar to that of FIG. 2, except that the interconnect bridge 219 is a multilayer structure comprising a plurality of metallization layers with an electrically insulating substrate region. The structured metallization layers may comprise or be plated with any or more of Cu, Ni, Ag, Au, Pd, Pt, NiV, NiP, NiNIP, NiP/Pd, Ni/Au, NiP/Pd/Au, or NiP/Pd/AuAg. The electrically insulating substrate may comprise a ceramic material such as Al₂O₃ (Alumina) AlN (Aluminium Nitride), etc., or filled polymer materials such as epoxy resin or polyimide. The construction of the interconnect bridge 219 can resemble that of a power electronics carrier such as a Direct Copper Bonding (DCB) substrate, a Direct Aluminium Bonding (DAB) substrate, an Isolated Metal Substrate (IMS) or an Active Metal Brazing (AMB) substrate, for example.

According to an embodiment, the isolation structure 105 that provides galvanic isolation between the input driver circuit 112 and the output driver circuit 114 is monolithically integrated into the interconnect bridge 219. Thus, the interconnect bridge 219 has the dual functionality of providing electrical interconnect between the second load terminals 214 of the first and second power transistor dies 210, 212 and providing dielectric isolation between the input side 104 of the semiconductor package 100 and the output side 108 of the semiconductor package 100. The multilayer configuration of the interconnect bridge 219 is used to create a galvanic isolation structure 105. For example, the galvanic isolation structure 105 may be a capacitive coupler that provides galvanic isolation between a first metal pad formed in a first upper metallization layer and a second metal pad formed in a second lower metallization layer that is separated from the first metal pad from the interconnect bridge 219. Other types of galvanic isolations may be monolithically integrated in the interconnect bridge 219, including so-called coreless transformers and inductive couplers.

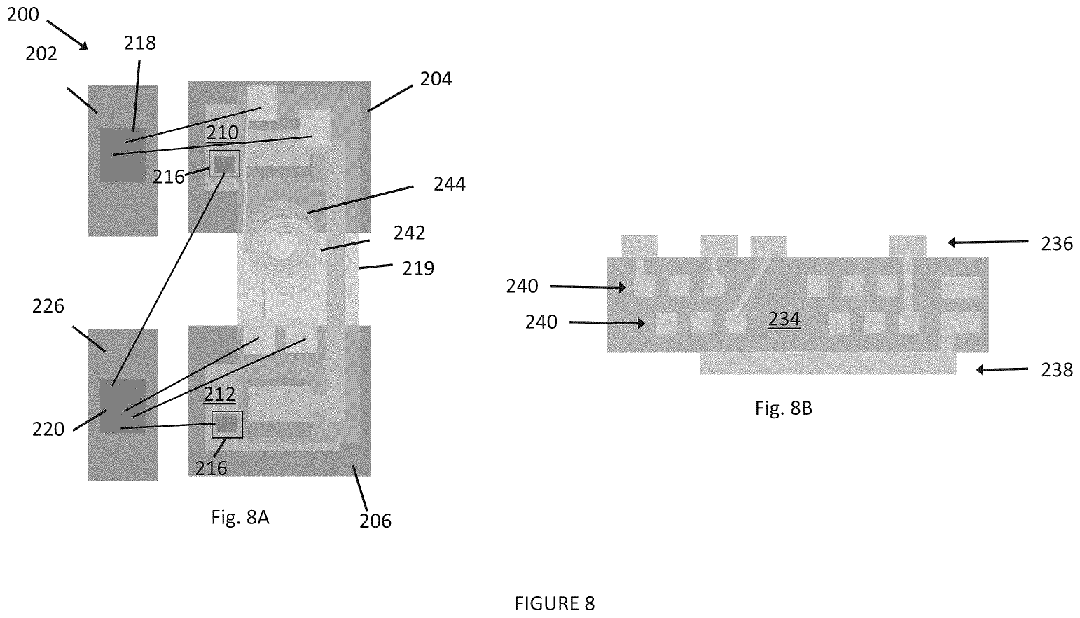

Referring to FIG. 8, an assembly used to form the semiconductor package 100 is shown, according to another embodiment. The assembly of FIG. 8 comprises a circuit carrier 200 that is configured as a lead frame in a similar manner as the embodiment described with reference to FIG. 5, except that the layout of the input device die pad 202, the first output device pad 204, the second output device pad 206, and the third output device pad 226 is modified. In particular, the input device die pad 202 is arranged adjacent to the first output device pad 204 and the third output device die pad 226 is arranged adjacent to the second output device pad 206. Similar to the previously described embodiment, the interconnect bridge 219 is a multilayer structure comprising a plurality of metallization layers with an electrically insulating substrate 234 in between the first and second metallization layers 236, 238. In this case, the interconnect bridge 219 is constructed in a similar manner as a printed circuit board (PCB). The electrically insulating substrate may be formed from a laminate material, e.g., resin fiber material such as FR-4. The PCB construction of the interconnect bridge 219 allows for the provision of metallization layers within the electrically insulating substrate 234. As shown, the interconnect bridge 219 comprises two interior metallization layers 240 that are embedded within the electrically insulating substrate 234. In this embodiment, the interconnect bridge 219 comprises a coreless transformer that provides the galvanic isolation structure 105 and is formed by first and second coils 242, 244 that are inductively coupled to one another and formed in the interior metallization layers of the interconnect bridge 219.

The term “interconnect bridge” as used herein refers one or more structures disposed in a lateral space separating two transistor dies that forms an electrically conductive path between the two transistor dies. An interconnect bridge 219 may include a completely electrically conductive structure, such as a metal interconnect clip or ribbon. An interconnect bridge 219 may also include a multi-layered structure that comprises electrically conductive features formed on or within an electrical insulator, for example a structure a power electronics carrier or a PCB.

The term “interconnect clip” as as used herein refers to a specific type of electrical interconnect structure that is used to provide an electrical connection between two conductive surfaces in a semiconductor package. A metal interconnect clip is a rigid metal structure that is formed from an undisturbed planar sheet metal, e.g., in a similar or identical technique used to form a package lead frame. A metal interconnect clip may be a section of this planar sheet metal that is cut and bent into a desired shape. An interconnect clip generally offers significantly lower electrical resistance than bond wire connections and may have greater current carrying capacity than bond wires of the same length, all other factors being equal. A “metal interconnect clip” may comprise or be plated with any one or more of: Cu, Al, Ni, Ag, Au, Pd, Pt.

The term “interconnect ribbon” as used herein refers to a specific type of electrical interconnect structure that is used to provide an electrical connection between two conductive surfaces in a semiconductor package 100. An interconnect ribbon is formed from a conductive metal and has a flattened cross-sectional footprint with a width that exceeds its thickness. An interconnect ribbon generally offers significantly lower electrical resistance than bond wire connections and may have greater current carrying capacity than bond wires of the same length, all other factors being equal. Interconnect ribbons are less rigid than metal interconnect clips such that they may be manipulated during assembly. Moreover, whereas metal interconnect clips are typically affixed to other metal surfaces by an intermediary material, e.g., solder, sinter, an “interconnect ribbon” may be directly bonded to another surface in a process akin to wire bonding. An “interconnect ribbon” may comprise or be plated with any one or more of: Cu, Al, Ni, Ag, Au, Pd, Pt.

As used herein, the term “pin” refers to an externally accessible terminal of a semiconductor package. Examples of pins include conducive leads, metal contacts, and bond pads that are configured for external connection. These structures may be externally connected to another device such as a PCB or power electronics carrier using a connection technique such as soldering or sintering.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although the present disclosure is not so limited, the following numbered examples demonstrate one or more aspects of the disclosure.

Example 1. A semiconductor package, comprising: an input side comprising one or more input pins; an output side comprising a plurality of high voltage pins; an isolation structure that galvanically isolates the input side from the output side; an input driver die mounted on the input side and electrically connected with the one or more input pins; first and second power transistor dies mounted on the output side and each having a first load terminal electrically connected with one of the high voltage pins; an output driver die that is communicatively coupled to the input driver die driver die via the isolation structure and is electrically connected with gate terminals of the first and second power transistor dies; and one or more electrically conductive structures forming a direct electrical connection between second load terminals of the first and second power transistor dies, wherein the output driver die is mounted on at least one of the one or more electrically conductive structures.

Example 2. The semiconductor package of example 1, wherein the semiconductor package comprises first and second output device pads, wherein the first power transistor die is mounted on the first output device pad with the second load terminal of the first power transistor die facing away from the first output device pad, wherein the second power transistor die is mounted on the second output device pad with the second load terminal of the second power transistor die facing away from the second output device pad, and wherein the one or more electrically conductive structures comprise one or more interconnect elements that are attached to the second load terminals of the first and second power transistor dies and extend across a gap between the first and second output device die pads.

Example 3. The semiconductor package of example 2, wherein the one or more interconnect elements comprises an interconnect bridge that is mounted on top of the first and second power transistor dies and extends directly from the second load terminal of the first power transistor die to the second load terminal of the second power transistor die, and wherein the output driver die is mounted on top of the interconnect bridge.

Example 4. The semiconductor package of example 3, wherein the interconnect bridge is a metal clip.

Example 5. The semiconductor package of example 2, wherein the one or more electrically conductive structures comprises a third output device die pad of the semiconductor package that is disposed between the first and second output device die pads, and wherein the output driver die is mounted on the third output device die pad.

Example 6. The semiconductor package of example 5, wherein the one or more interconnect elements comprises bond wires that are electrically connected between the second load terminals of the first and second power transistor dies and the third output device die pad.

Example 7. The semiconductor package of example 5, wherein the semiconductor package comprises a power electronics carrier with a first structured metallization layer disposed on an electrically insulating substrate, and wherein each of the first, second and third output device die pads are structured regions of the first structured metallization layer.

Example 8. The semiconductor package of example 1, wherein the output driver die is configured as a current sensor to sense a current flowing between the second load terminals of the first and second power transistor dies.

Example 9. A semiconductor package, comprising: an input side comprising an input pin; an output side comprising high voltage pins; an isolation structure that galvanically isolates the input side from the output side; an input driver die driver die mounted on the input side and electrically connected with the input pin; first and second power transistor dies mounted on the output side and each having a first load terminal electrically connected with one of the high voltage pins; an output driver die comprising an input terminal that is communicatively coupled to the input driver die driver die via the isolation structure and output terminals that are electrically connected with gate terminals of the first and second power transistor dies; and an interconnect bridge that is mounted over the first and second power transistor dies and extends directly from a second load terminal of the first power transistor die to a second load terminal of the second power transistor die, wherein the isolation structure is integrally formed within the interconnect bridge.

Example 10. The semiconductor package of example 9, wherein the interconnect bridge comprises first and second metallization layers and an electrically insulating substrate arranged between the first and second metallization layers, and wherein the input side is galvanically isolated from the output side by the electrically insulating substrate.

Example 11. The semiconductor package of example 10, wherein the electrically insulating substrate is a ceramic layer, and wherein the isolation structure is configured as a capacitive coupler.

Example 12. The semiconductor package of example 10, wherein the electrically insulating substrate comprises laminate material, and wherein the isolation structure comprises a coreless transformer with windings that are embedded within the electrically insulating substrate.

Example 13. The semiconductor package of example 9, wherein output driver die is mounted on the interconnect bridge.

Example 14. A method of forming a semiconductor package, the method comprising: providing a circuit carrier that comprises a first input device pad, first and second output device die pads, a plurality of input pins, and a plurality of output pins; mounting an input driver die driver die on the first input device pad and electrically connecting the input driver die to one of the input pins; mounting first and second power transistor dies on the first and second output device die pads, respectively, and electrically connecting first load terminals of the first and second power transistor dies with the output pins; providing an isolation structure that galvanically isolates an input side of the semiconductor package from an output side of the semiconductor package; and mounting an output driver die on the output side of the semiconductor package such that the output driver die is communicatively coupled to the input driver die driver die via the isolation structure and is electrically connected with gate terminals of the first and second power transistor dies; forming a direct electrical connection between second load terminals of the first and second power transistor dies; and forming an electrically insulating encapsulant body that encapsulates each of the input driver die, the output driver die driver, and the first and second power transistor dies, wherein the output driver die is mounted on one or more electrically conductive structures that form a direct electrical connection between second load terminals of the first and second power transistor dies.

Example 15. The method of example 14, wherein the circuit carrier is a metal lead frame.

Example 16. The method of example 15, wherein the metal lead frame comprises a third output device die pad, and wherein the one or more electrically conductive structures comprises the third output device die pad, and wherein the method further comprises mounting the output driver die on the third output device die pad.

Example 17. The method of example 16, wherein providing the circuit carrier comprises providing a lead frame strip with a tie bar connected between the third output device die pad and a dambar of the lead frame strip, and wherein the method further comprises severing the tie bar such that an outer end of the tie bar is spaced apart from an outer edge side of the electrically insulating encapsulant body.

Example 18. The method of example 17, wherein severing the tie bar comprises any one of: physical cutting, laser cutting, punching, and stamping.

Example 19. The method of example 17, wherein the method further comprises providing a first interconnect element between the second load terminal of the first power transistor die and the third output device die pad and forming a second interconnect element between the second load terminal of the second power transistor die and the third output device die pad, and wherein the output device die pad is suspended by the first interconnect element and the second interconnect element after severing the tie bar and before forming the electrically insulating encapsulant body.

Example 20. The method of example 14, wherein the circuit carrier is a power electronics carrier.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor package, comprising:
an input side comprising one or more input pins;
an output side comprising a plurality of high voltage pins;
an isolation structure that galvanically isolates the input side from the output side;
an input driver die mounted on the input side and electrically connected with the one or more input pins;
first and second power transistor dies mounted on the output side and each having a first load terminal electrically connected with one of the high voltage pins;
an output driver die that is communicatively coupled to the input driver die driver die via the isolation structure and is electrically connected with gate terminals of the first and second power transistor dies; and
one or more electrically conductive structures forming a direct electrical connection between second load terminals of the first and second power transistor dies,
wherein the output driver die is mounted on at least one of the one or more electrically conductive structures.

2. The semiconductor package of claim 1, wherein the semiconductor package comprises first and second output device pads, wherein the first power transistor die is mounted on the first output device pad with the second load terminal of the first power transistor die facing away from the first output device pad, wherein the second power transistor die is mounted on the second output device pad with the second load terminal of the second power transistor die facing away from the second output device pad, and wherein the one or more electrically conductive structures comprise one or more interconnect elements that are attached to the second load terminals of the first and second power transistor dies and extend across a gap between the first and second output device die pads.

3. The semiconductor package of claim 2, wherein the one or more interconnect elements comprises an interconnect bridge that is mounted on top of the first and second power transistor dies and extends directly from the second load terminal of the first power transistor die to the second load terminal of the second power transistor die, and wherein the output driver die is mounted on top of the interconnect bridge.

4. The semiconductor package of claim 3, wherein the interconnect bridge is a metal clip.

5. The semiconductor package of claim 2, wherein the one or more electrically conductive structures comprises a third output device die pad of the semiconductor package that is disposed between the first and second output device die pads, and wherein the output driver die is mounted on the third output device die pad.

6. The semiconductor package of claim 5, wherein the one or more interconnect elements comprises bond wires that are electrically connected between the second load terminals of the first and second power transistor dies and the third output device die pad.

7. The semiconductor package of claim 5, wherein the semiconductor package comprises a power electronics carrier with a first structured metallization layer disposed on an electrically insulating substrate, and wherein each of the first, second and third output device die pads are structured regions of the first structured metallization layer.

8. The semiconductor package of claim 1, wherein the output driver die is configured as a current sensor to sense a current flowing between the second load terminals of the first and second power transistor dies.

9. A semiconductor package, comprising:
an input side comprising an input pin;
an output side comprising high voltage pins;
an isolation structure that galvanically isolates the input side from the output side;
an input driver die driver die mounted on the input side and electrically connected with the input pin;
first and second power transistor dies mounted on the output side and each having a first load terminal electrically connected with one of the high voltage pins;
an output driver die comprising an input terminal that is communicatively coupled to the input driver die driver die via the isolation structure and output terminals that are electrically connected with gate terminals of the first and second power transistor dies; and
an interconnect bridge that is mounted over the first and second power transistor dies and extends directly from a second load terminal of the first power transistor die to a second load terminal of the second power transistor die,
wherein the isolation structure is integrally formed within the interconnect bridge.

10. The semiconductor package of claim 9, wherein the interconnect bridge comprises first and second metallization layers and an electrically insulating substrate arranged between the first and second metallization layers, and wherein the input side is galvanically isolated from the output side by the electrically insulating substrate.

11. The semiconductor package of claim 10, wherein the electrically insulating substrate is a ceramic layer, and wherein the isolation structure is configured as a capacitive coupler.

12. The semiconductor package of claim 10, wherein the electrically insulating substrate comprises laminate material, and wherein the isolation structure comprises a coreless transformer with windings that are embedded within the electrically insulating substrate.

13. The semiconductor package of claim 9, wherein output driver die is mounted on the interconnect bridge.

14. A method of forming a semiconductor package, the method comprising:
providing a circuit carrier that comprises a first input device pad, first and second output device die pads, a plurality of input pins, and a plurality of output pins;
mounting an input driver die driver die on the first input device pad and electrically connecting the input driver die to one of the input pins;
mounting first and second power transistor dies on the first and second output device die pads, respectively, and electrically connecting first load terminals of the first and second power transistor dies with the output pins;
providing an isolation structure that galvanically isolates an input side of the semiconductor package from an output side of the semiconductor package; and
mounting an output driver die on the output side of the semiconductor package such that the output driver die is communicatively coupled to the input driver die driver die via the isolation structure and is electrically connected with gate terminals of the first and second power transistor dies;
forming a direct electrical connection between second load terminals of the first and second power transistor dies; and
forming an electrically insulating encapsulant body that encapsulates each of the input driver die, the output driver die driver, and the first and second power transistor dies,
wherein the output driver die is mounted on one or more electrically conductive structures that form a direct electrical connection between second load terminals of the first and second power transistor dies.

15. The method of claim 14, wherein the circuit carrier is a metal lead frame.

16. The method of claim 15, wherein the metal lead frame comprises a third output device die pad, and wherein the one or more electrically conductive structures comprises the third output device die pad, and wherein the method further comprises mounting the output driver die on the third output device die pad.

17. The method of claim 16, wherein providing the circuit carrier comprises providing a lead frame strip with a tie bar connected between the third output device die pad and a dambar of the lead frame strip, and wherein the method further comprises severing the tie bar such that an outer end of the tie bar is spaced apart from an outer edge side of the electrically insulating encapsulant body.

18. The method of claim 17, wherein severing the tie bar comprises any one of: physical cutting, laser cutting, punching, and stamping.

19. The method of claim 17, wherein the method further comprises providing a first interconnect element between the second load terminal of the first power transistor die and the third output device die pad and forming a second interconnect element between the second load terminal of the second power transistor die and the third output device die pad, and wherein the output device die pad is suspended by the first interconnect element and the second interconnect element after severing the tie bar and before forming the electrically insulating encapsulant body.

20. The method of claim 14, wherein the circuit carrier is a power electronics carrier.
